(19) United States
(12) Patent Application Publication
(10) Pub. No.: US 2014/0159078 A1
(43) Pub. Date: Jun. 12, 2014

(54) DISPLAY DEVICE AND METHOD OF MANUFACTURING THE SAME

(71) Applicant: Samsung Display Co., Ltd., Yongin-city (KR)

(72) Inventor: Jun-Young Kim, Yongin-city (KR)

(73) Assignee: Samsung Display Co., Ltd., Yongin-city (KR)

(21) Appl. No.: 14/037,242

(22) Filed: Sep. 25, 2013

(30) Foreign Application Priority Data
Dec. 11, 2012 (KR) 10-2012-0143834

(51) Int. Cl. H01L 33/08

(52) U.S. Cl. CPC H01L 33/08
USPC 257/89; 438/33

(57) ABSTRACT

A display device and a method of manufacturing the display device are disclosed. In one aspect, the display device includes a first substrate, a light-emitting portion formed on the first substrate, and a sealing portion which is attached to the first substrate so as to shield the light-emitting portion from ambient environmental conditions. At least a portion of an edge of the first substrate is chamfered.

### CROSS-REFERENCE TO RELATED APPLICATIONS

This application claims the benefit of Korean Patent Application No. 10-2012-0143834, filed on Dec. 11, 2012, in the Korean Intellectual Property Office, the disclosure of which is incorporated herein in its entirety by reference.

### BACKGROUND

1. Field

The present invention relates to a device and a method of manufacturing the device, and more particularly, to a display device and a method of manufacturing the display device.

2. Description of the Related Technology

A conventional deposition apparatus includes a substrate holder having a substrate mounted thereon, a heating crucible (or evaporation boat) containing an electroluminescent (EL) material, i.e., a deposition material, a shutter for preventing an EL material to be sublimed from rising, and a heater for heating the EL material in the heating crucible. The EL material heated by the heater is sublimed and deposited on a rotating substrate. In order to form a uniform film, the distance between the substrate and the heating crucible should typically be at least 1 meter.

Since precision in film formation is not high, wide gaps between different pixels may be designed, or an insulator called a bank may be formed between pixels when the manufacture of a full color flat panel display using red (R), green (G), and blue (B) light colors is considered.

Furthermore, the demand for full color flat panel displays with high resolution (i.e., a large number of pixels), high aperture ratio, and high reliability is increasing. However, such demand is challenging because the pitch in each organic light-emitting layer becomes finer as the resolution (number of pixels) and size (form factor) of the light-emitting device increases. Demand for high productivity and low manufacturing costs is also ever present.

### SUMMARY OF CERTAIN INVENTIVE ASPECTS

The present invention provides a display device and a method of manufacturing the display device which allow strong adhesion between upper and lower films during hybrid patterning.

According to an aspect of the present invention, there is provided a display device, comprising: a first substrate; a light-emitting portion formed on the first substrate; and a sealing portion which is attached to the first substrate so as to protect the light-emitting portion from ambient environmental conditions wherein at least a portion of an edge of the first substrate is chamfered.

The edge of the first substrate has a triangular cross-section in a thickness dimension.

The edge of the first substrate may be chamfered from one surface of the first substrate on which the light-emitting portion is formed towards an edge thereof.

Alternatively, the edge of the first substrate is chamfered from the other surface of the first substrate on which the light-emitting portion is not formed towards an edge thereof.

Distal ends of the first substrate are respectively chamfered from both surfaces of the first substrate towards edges of the first substrate.

The light-emitting portion may include an organic emission layer, and wherein the organic emission layer includes at least one of a blue emission layer, a red emission layer, a green emission layer, and a white emission layer.

The blue emission layer is formed by using a fine metal mask process.

At least one of the red and green emission layers is formed by using a laser-induced thermal imaging (LITI) process.

The white emission layer is formed from a stack of the blue, red and green emission layers.

According to another aspect of the present invention, there is provided a method of manufacturing a display device, the method comprising: providing a first substrate with chamfered edges; stacking a buffer layer, an active layer, a gate insulating layer, a gate electrode, an interlayer insulating layer, a source electrode, a drain electrode, a passivation layer, a pixel-defining layer, and a pixel electrode on the first substrate in this order; and forming, by a fine metal mask process and a laser-induced thermal imaging (LITI) process, an organic emission layer on the pixel electrode in a pixel defined by the pixel-defining layer.

The edges of the first substrate are chamfered by using a polishing process.

The forming of the organic emission layer includes depositing a blue emission layer on the pixel electrode by using the fine metal mask process and transferring green and red emission layers onto the pixel electrode by using the LITI process.

The LITI process includes transferring the green emission layer onto the pixel electrode and then depositing the red emission layer on the pixel electrode.

The transferring of the green and red emission layers onto the pixel electrode by the LITI process includes: seating the first substrate on a lower film; preparing an upper film by depositing a transfer layer having one of the red and green emission layers patterned thereon on a base film; disposing the upper film on the first substrate and laminating the upper and lower films by venting; and irradiating the upper film with a laser beam and transferring the one of the red and green emission layers onto the pixel electrode.

The transferring of the green and red emission layers onto the pixel electrode further includes removing the upper and lower films after irradiation with the laser beam.

The method of manufacturing a display device further comprising forming an opposite electrode on the pixel-defining layer on which the organic emission layer has been formed and sealing the opposite electrode with a sealing portion.

The manufacturing method further comprising cutting the first substrate into a plurality of substrates and separating the plurality of substrates from one another.

The forming of the organic emission layer includes forming a white emission layer by depositing or transferring blue, green, and red emission layers.

The display device and the method of manufacturing the display device allow complete attachment between the upper and lower films at edges of the first substrate, thereby improving an adhesion force therebetween.

The display device and the manufacturing method also eliminate a portion where the upper film is not attached to the lower film due to the thickness of the first substrate to thereby prevent movement of the first substrate and allow transfer of the organic emission layer onto a precise location on the pixel-defining layer.

In particular, the display device thus manufactured allows the transfer of the organic emission layer onto the precise location, thereby providing increased brightness and reproducibility.

### BRIEF DESCRIPTION OF THE DRAWINGS

The above and other features and advantages of the disclosed technology will become more apparent by describing in detail exemplary embodiments thereof with reference to the attached drawings in which:

FIG. 1 is a conceptual diagram of a display device according to an embodiment of the disclosed technology;

FIG. 2 is a cross-sectional view of a first substrate and a light-emitting portion shown in FIG. 1;

FIG. 3 is a cross-sectional view illustrating a process of forming an emission layer (EML) shown in FIG. 2 according to an embodiment of the disclosed technology;

FIG. 4 is a cross-sectional view illustrating a process of forming the EML shown in FIG. 2, according to another embodiment of the disclosed technology; and

FIG. 5 is a cross-sectional view illustrating a process of forming the EML shown in FIG. 2, according to another embodiment of the disclosed technology.

### DETAILED DESCRIPTION OF CERTAIN INVENTIVE EMBODIMENTS

Example embodiments of the invention will now be described more fully hereinafter with reference to the accompanying drawings, in which exemplary embodiments of the invention are shown. This invention may, however, be embodied in many different forms and should not be construed as limited to the exemplary embodiments set forth herein. Rather, the exemplary embodiments are provided so that this disclosure will be thorough and complete, and will fully convey the scope of the invention to those skilled in the art. The scope of the present invention is defined only by the appended claims. The terminology used herein is of describing particular exemplary embodiments only and is not intended to limit the invention. As used herein, the singular forms “a”, “an”, and “the” are intended to include the plural forms as well, unless the context clearly indicates otherwise. It will be further understood that the terms “comprises” and/or “comprising” or “includes” and/or “including” when used in this specification, specify the presence of components, steps, operations and/or elements, but do not preclude the presence or addition of one or more other components, steps, operations, and/or elements. As used herein, the term “and/or” includes any and all combinations of one or more of the associated listed items. Expressions such as “at least one of” when preceding a list of elements, modify the entire list of elements and do not modify the individual elements of the list.

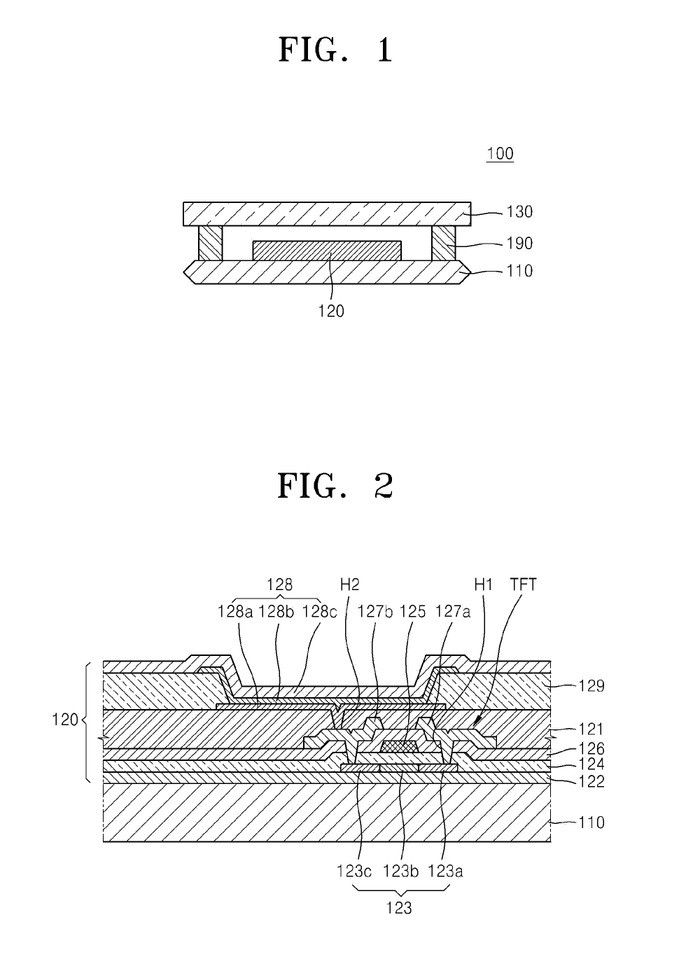

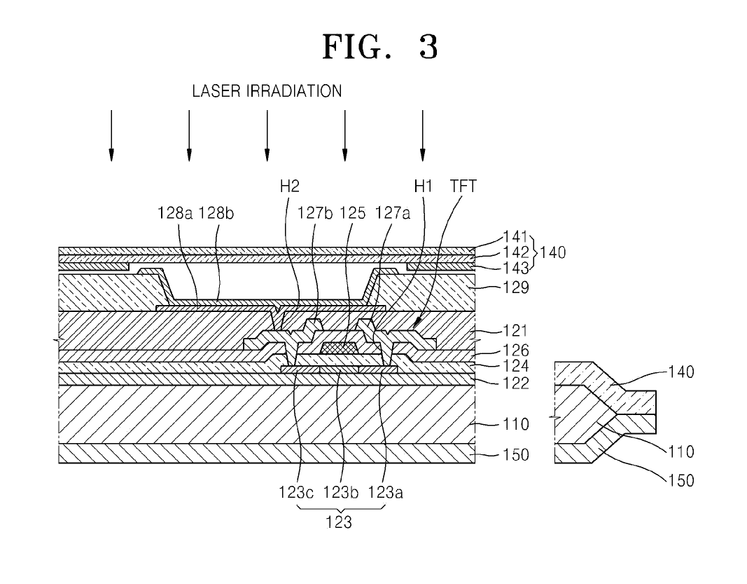

FIG. 1 is a conceptual diagram of a display device 100 according to an embodiment of the disclosed technology. FIG. 2 is a cross-sectional view of a first substrate 110 and a light-emitting portion 120 shown in FIG. 1. FIG. 3 is a cross-sectional view illustrating a process of forming an emission layer (EML) shown in FIG. 2.

Referring to FIGS. 1 through 3, the display device 100 includes the first substrate 110, a sealing portion 130, a sealing member 190 and the light-emitting portion 120. At least portions of edges of the first substrate 110 are chamfered. More specifically, the first substrate 110 may have sloped edges formed through polishing. The light-emitting portion 120 is disposed on the first substrate 110 and includes a thin-film transistor (TFT), a passivation layer 121 covering the TFT, and an organic light-emitting diode (OLED) overlying the passivation layer 121.

The first substrate 110 may be made of glass, but it is not limited thereto. The first substrate 110 may be formed of a plastic material or a metallic material such as SUS or Ti.

Now referring, more particularly, to FIGS. 2 & 3, for the purpose of explanation only one portion of a pixel circuit of the light emitting portion 120 will be described. However, it will be recognized that a display will typically be formed of a matrix of such pixel circuits arranged in many rows and columns. In the depicted pixel circuit portion a buffer layer 122 of an organic and/or inorganic compound may be formed over the first substrate 110. For example, the buffer layer 122 may be made of silicon oxide (SiOx, x≧1) or silicon nitride (SiNx, x≧1).

An active layer 123 is arranged on the buffer layer 122 in a predetermined pattern, and buried in a gate insulating layer 124. The active layer 123 includes a source region 123a, a drain region 123c, and a channel region 123b interposed therebetween. The active layer 123 is made of amorphous silicon, but it is not limited thereto. The active layer 123 may be formed of oxide semiconductor. For example, the oxide semiconductor may include an oxide of a material selected from the group consisting of metals in groups 12, 13, and 14, such as zinc (Zn), indium (In), gallium (Ga), tin (Sn), cadmium (Cd), germanium (Ge) and hafnium (Hf), and mixtures thereof. For example, the active layer 123 may include G-I-Z-O [(In2O3)a(Ga2O3)b(ZnO)c] where a, b, and c are real numbers satisfying a≧0, b≧0, and c>0. For convenience of explanation, it is assumed herein that the active layer 123 is made of amorphous silicon.

Formation of the active layer 123 may include forming an amorphous silicon layer on the buffer layer 122, crystallizing the amorphous silicon layer into a polycrystalline silicon layer, and patterning the polycrystalline silicon layer. The source and drain regions 123a and 123c in the active layer 123 are doped with n- or p-type impurities depending on the type of the TFT used, such as a driving TFT (not shown) or a switching TFT (not shown).

A gate electrode 125 corresponding to the active layer 123 and an interlayer insulating layer 126 burying the gate electrode 125 are formed on the gate insulating layer 124.

After forming contact holes in the interlayer insulating layer 126 and the gate insulating layer 124, a source electrode 127a and a drain electrode 127b are disposed on the interlayer insulating layer 126 so as to contact the source region 123a and the drain region 123c, respectively.

Since the source and drain electrodes 127a and 127b also serve as a reflective layer the source and drain electrodes 127a and 127b may be formed of a material having high electrical conductivity and be thick enough to reflect light. For example, the source and drain electrodes 127a and 127b may be formed of a metallic material such as silver (Ag), magnesium (Mg), aluminum (Al), platinum (Pt), palladium (Pd), gold (Au), nickel (Ni), neodymium (Nd), iridium (Jr), chromium (Cr), lithium (Li), calcium (Ca), or a compound thereof.

The passivation layer 121 is formed on the TFT and the reflective layer, and a pixel electrode 128a of the OLED is disposed on the passivation layer 121 so as to contact the drain electrode 127b of the TFT through a via hole H2 (FIGS. 2 & 3). The passivation layer 121 may be formed of a single layer or at least two layers of an inorganic and/or organic material. The passivation layer 121 may be a planarization layer having a planarized top surface regardless of an uneven topology of the underlying layer, or may have a curved surface which follows a curvature of a surface of the underlying layer. The passivation layer 121 may also be a transparent insulator in order to achieve a resonance effect.

After forming the pixel electrode 128a on the passivation layer 121, a pixel-defining layer 129 of an organic and/or inorganic material is formed so as to cover the pixel electrode 128a and the passivation layer 121, and an opening is formed to expose the pixel electrode 128a.

An organic layer 128b and an opposite electrode 128c are disposed on at least the pixel electrode 128a.

The pixel electrode 128a and the opposite electrode 128c act as an anode and a cathode, respectively. However, an embodiment is not limited thereto, and the pixel electrode 128a and the opposite electrode 128c may act as a cathode and an anode, respectively.

The pixel electrode 128a may be formed of a material with a high work function, e.g., a transparent conducting material such as indium tin oxide (TTO), indium zinc oxide (IZO), indium oxide (In2O3), or zinc oxide (ZnO).

The opposite electrode 128c may be formed of a metallic material with a low work function, such as Ag, Mg, Al, Pt, Pd, Au, Ni, Nd, Jr, Cr, Li, Ca, or a compound thereof. Alternatively, it may be formed as a thin semi-transparent reflective layer of Mg, Ag, and Al so as to transmit light after optical resonance.

The pixel electrode 128a and the opposite electrode 128c are insulated from each other by the organic layer 128b, and during operation of the display device, apply voltages of opposite polarity to the organic layer 128b so that light is emitted by an emission layer.

The organic layer 128b may be a low molecular weight or polymeric organic layer. When the organic layer 128b is a low molecular weight organic layer, the organic layer 128b may have a single- or multi-layered structure including a stack of a hole injection layer (HIL), a hole transport layer (HTL), an emission layer (EML), an electron transport layer (ETL), and an electron injection layer (EIL). An organic material for use in the organic layer 128b may be copper phthalocyanine (CuPc), N,N′-Di (naphthalene-1-yl)-N,N′-diphenyl-benzidine (NPB), tris-8-hydroxyquinoline aluminum (Alq3), or other various materials. In this case, the organic layer 128b may be formed by vacuum deposition. Like the opposite electrode 128c, the HIL, the HTL, and ETL which are common to red, green, and blue pixels may be formed so as to cover all the pixels.

On the other hand, when the organic layer 128b is a polymeric organic layer, the organic layer 128b mainly includes an HTL and an EML. poly(3,4-ethylenedioxythiophene) (PEDOT) is used as the HTL, and Poly-Phenylenevinylene (PPV)- or Polyfluorene-based polymeric organic material is used as the EML. In this case, the organic layer 128b may be formed by screen printing, inkjet printing, a fine metal mask method, or laser-induced thermal imaging (LITI).

However, the organic layer 128b is not limited thereto, and the organic layer 128b may be formed by other methods.

The sealing portion 130 is used to protect the materials in the light emitting portion 120 that may decay when exposed to oxygen, water and light, for example, and may be formed in a similar way to the first substrate 110. More specifically, like the first substrate 110, the sealing portion 130 may be made of glass. However, the sealing portion 130 is not limited thereto, and it may be made of a plastic material. The sealing portion 130 may be formed by alternately stacking at least one organic and one inorganic layer. The sealing portion 130 may include a plurality of inorganic layers and a plurality of organic layers.

The organic layer may be composed of a single layer of one of polymers, e.g., polyethylene terephthalate, polyimide, polycarbonate, epoxy, polyethylene, and polyacrylate, or a stack of multiple layers thereof. The organic layer may be formed of polyacrylate by polymerization of a monomer composition containing a diacrylate monomer and a triacrylate monomer. The monomer composition may further include monoacrylate monomer. The monomer composition may further contain a known photoinitiator such as TPO, but it is not limited thereto.

The inorganic layer may be composed of a single layer of metal oxide or metal nitride or a stack of multiple layers thereof. More specifically, the inorganic layer may include one of SiNx, aluminum oxide (Al2O3), silicon dioxide (SiO2), and titanium oxide (TiO2). An exposed uppermost layer in the sealing portion 130 may be an inorganic layer in order to prevent permeation of moisture into the OLED.

The sealing portion 130 may have at least one sandwich structure including at least two inorganic layers and at least one organic layer interposed therebetween. Alternatively, the at least one sandwich structure may include at least two organic layers and at least one inorganic layer interposed therebetween.

The sealing portion 130 may include a first inorganic layer, a first organic layer, and a second inorganic layer stacked in this order when viewed from the top of the light-emitting portion 120. The sealing portion 130 may also include a first inorganic layer, a first organic layer, a second inorganic layer, a second organic layer, and a third inorganic layer sequentially stacked from the top of the light-emitting portion 120. Alternatively, the sealing portion 130 may include a first inorganic layer, a first organic layer, a second inorganic layer, a second organic layer, a third inorganic layer, a third organic layer, and a fourth inorganic layer sequentially stacked from the top of the light-emitting portion 120.

A metal halide layer containing lithium fluoride (LiF) may also be formed between the light-emitting portion 120 and the first inorganic layer to prevent damage to the light-emitting portion 120 during sputtering or plasma deposition for forming the first inorganic layer.

The first and second organic layers may respectively have areas smaller than those of the second and third inorganic layers. Furthermore, the second and third inorganic layers may completely cover the first and second organic layers, respectively.

For convenience of explanation, it is assumed herein that the sealing portion 130 is made of glass which is the same material as that of the first substrate 110.

A method of manufacturing the display device 100 will now be described in detail.

First, a first substrate 110 is prepared with its edges chamfered by mechanical polishing. In these embodiments, the edges of the first substrate 110 may have a triangular cross-section in the thickness dimension of the first substrate 110. In particular, the edges of one surface and the other surface of the first substrate 110 may be simultaneously chamfered. Thus, the edges of the first substrate 110 are sloped from two surfaces of the first substrate 110 towards edges thereof.

When the first substrate 110 is large in size, a single substrate is used as the first substrate 110. Conversely, when the first substrate 110 is small in size, a mother substrate (not shown) including a plurality of the first substrates 110 may be used. Since the display device 100 is manufactured in a similar manner regardless of the size of the first substrate 110, for convenience of explanation, it is assumed herein that the first substrate 110 is a single substrate.

The first substrate 110 may have various shapes including a circle, a rectangle, and a polygon. For convenience of explanation, the first substrate 110 is assumed to have a rectangular shape.

The first substrate 110 having a rectangular shape may have at least one edge chamfered in a similar way as described above. For convenience of explanation, however, it is assumed herein that all four edges of the first substrate 110 are chamfered.

After preparing the first substrate 110 with the chamfered edges, a buffer layer 122, an active layer 123, a gate insulating layer 124, a gate electrode 125, an interlayer insulating layer 126, a source electrode 127a, a drain electrode 127b, a passivation layer 121, a pixel-defining layer 129, and a pixel electrode 128a are stacked on the first substrate 110 in this order. Since the above stacking method is performed in the same or similar manner to a method of manufacturing a general display device, a detailed description thereof is omitted.

After stacking the respective layers on the first substrate 110, an EML may be formed on the pixel electrode 128a in a pixel defined by the pixel-defining layer 129 by using a fine metal mask method and an LITI method. The EML may be formed together with or separately from other layers described above. For convenience of explanation, it is assumed herein that the EML is formed separately from other layers.

When the EML is formed as described above, first, a blue EML is deposited on the pixel electrode 128a by using the fine metal mask, followed by formation of green and red EMLs. In such embodiments, at least one of the green and red EMLs may be transferred onto the pixel electrode 128a by using an LITI method. For convenience of explanation, it is assumed hereinafter that the green and red EMLs are sequentially transferred by using the LITI method.

Furthermore, the EML may further include various other color EMLs. In particular, the EML may include a white EML, and in such embodiments, the white EML may include blue, green, and red EMLs.

The white EML may be formed by using various methods. For example, the white EML may be formed by forming a blue EML by using a fine metal mask process and then stacking green and red EMLs on the blue EML by using an LITI method. The white EML may also be formed by stacking blue, green, and red EMLs during a fine metal mask process. Alternatively, the white EML may be formed by transferring blue, green, and red EMLs using an LITI method. However, for convenience of explanation, it is assumed hereinafter that only blue, green, and red EMLs are formed instead of a white EML.

In order to form the green EML, first, an upper film 140 is prepared. The upper film 140 may be formed by preparing a base film 141 and transferring a transfer layer 143 having the green EML patterned thereon onto the base film 141. The upper film 140 may further include a light-to-heat conversion layer 142 disposed between the base film 141 and the transfer layer 143. For convenience of explanation, it is assumed hereinafter that the upper film 140 includes the base film 141, the light-to-heat conversion layer 142, and the transfer layer 143.

Light emitted by a light source is absorbed in the light-to-heat conversion layer 142 on the base film 141 and converted into thermal energy. The thermal energy may cause a change in adhesion force among the first substrate 110 and the light-to-heat conversion layer 142 and the transfer layer 143 so that the material of the transfer layer 143 overlying the light-to-heat conversion layer 142 is transferred to the first substrate 110. Thus, an EML is patterned on the first substrate 110.

Simultaneously with preparing the upper film 140 as described above, a lower film 150 on which the first substrate 110 is seated is prepared. The upper film 140 may be disposed on the first substrate 110.

After completing the above-described arrangement, the upper and lower films 140 and 150 may be laminated with each other by venting. In this case, since the upper and lower films 140 and 150 have greater planar dimensions than the first substrate 110, they may be bonded to each other where they extend over the edges of the first substrate 110.

When the upper film 140 is attached to the lower film 150 as described above, the upper and lower films 140 and 150 may be bent to follow the chamfered shapes of the edges of the first substrate 110.

Of particular note, when upper and lower films are attached to each other according to conventional methods whereby an edge of a first substrate is not chamfered, the upper and lower films may not completely adhere to each other at edges of the first substrate.

Conversely, according to embodiments of the disclosed technology, the upper and lower films 140 and 150 can completely attach to each other at the edges of the first substrate 110 thereby substantially preventing their separation due to external shocks.

After completing adhesion between the upper and lower films 140 and 150 as described above, a laser beam is irradiated from above the upper film 140 to thereby transfer the green EML onto the pixel electrode 128a.

Following the above thermal transfer, the upper and lower films 140 and 150 are separated from the first substrate 110. Since a process of removing the upper and lower films 140 and 150 is performed in a similar manner to a general LITI process, a detailed description thereof will be omitted.

After transferring the green EML as described above, the red EML may be transferred by using a similar process to that for transferring the green EML. Thus, a detailed description thereof will be omitted.

Upon completion of the transfer of the green and red EMLs as described above, the opposite electrode 128c is formed on the pixel-defining layer 129. Since the opposite electrode 128c is formed in the same manner as generally known methods, a detailed description thereof will be omitted.

After forming the opposite electrode 128c, the first substrate 110 is attached to the sealing portion 130 by forming a sealing member 190 between the first substrate 110 and the sealing portion 130 and pressing together the first substrate 110 and the sealing portion 130 to form an airtight seal. Since the first substrate 110 is sealed to the sealing portion 130 by the sealing member 190 in a similar manner as a general sealing method used in manufacturing a display device, a detailed description thereof will be omitted.

When the sealing portion 130 is formed as a thin film as described above, lamination may be used.

In another embodiment, the display device 100 may be manufactured by performing the above-described process on a mother substrate including a plurality of the first substrates 110 and separating the plurality of the first substrates 110 from one another. Since a method of separating the first substrates 110 is the same as generally known separation methods, a detailed description thereof will be omitted.

As described above, the method of manufacturing the display device 100, according to the present embodiment, allows complete attachment between the upper and lower films 140 and 150 at edges of the first substrate 110, thereby improving the adhesive force therebetween.

The method also eliminates a portion where the upper film 140 is not attached to the lower film 150 due to the thickness of the first substrate 110 to thereby prevent movement of the first substrate 110 and allow transfer of an EML onto a precise location on the pixel-defining layer 129.

In particular, such precise EML can increase the brightness and reproducibility of the display device 100.

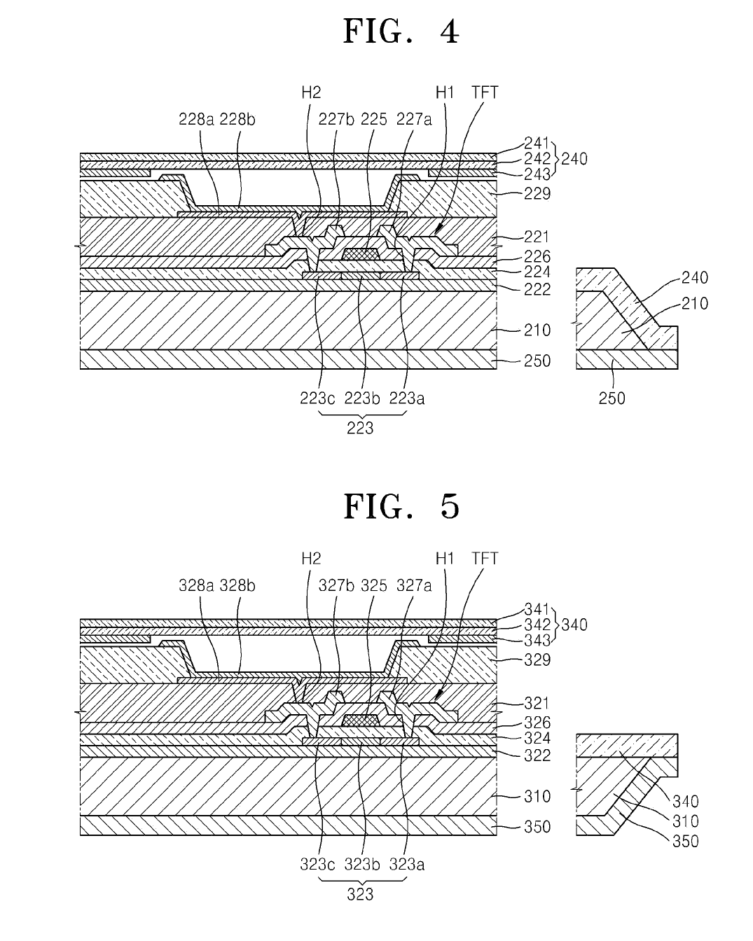

FIG. 4 is a cross-sectional view illustrating a process of forming the EML shown in FIG. 2, according to another embodiment of the disclosed technology. Hereinafter, like numbers refer to like elements.

Referring to FIG. 4, a display device (not indicated in FIG. 4) includes a first substrate 210, a sealing portion (not shown), and a light-emitting portion (not shown). Since the sealing portion and the light-emitting portion have the same or similar functions and structures as described above, detailed descriptions thereof will be omitted.

At least one edge of the first substrate 210 may be chamfered. More specifically, the first substrate 210 may have a sloped edge formed through a polishing process. In particular, the edge of the first substrate 210 may be sloped from one surface of the first substrate 110 on which the light-emitting portion is disposed towards an edge thereof.

A method of manufacturing the display device having the above-described structure will now be described in detail with reference to FIG. 4.

Referring to FIG. 4, first, the first substrate 210 is prepared with its edges chamfered by mechanical polishing. In this case, the edges of the first substrate 210 may have a triangular cross-section in a thickness direction of the first substrate 210. In particular, the edges of one surface of the first substrate 210 may be chamfered. Thus, the edges of the first substrate 210 may be sloped from the one surface of the first substrate 210 towards edges thereof.

When the first substrate 210 is large in size, a single substrate is used as the first substrate 210. Conversely, when the first substrate 210 is small in size, a mother substrate (not shown) including a plurality of the first substrates 210 may be used. Since the display device is manufactured in a similar manner regardless of the size of the first substrate 210, for convenience of explanation, it is assumed hereinafter that the first substrate 210 is a single substrate.

The first substrate 210 may have various shapes including a circle, a rectangle, and a polygon. For convenience of explanation, the first substrate 210 is assumed to have a rectangular shape.

The first substrate 210 having a rectangular shape may have at least one edge chamfered in a similar manner as described above. For convenience of explanation, however, it is assumed herein that all four edges of the first substrate 210 are chamfered.

Once the first substrate 210 with the chamfered edges is prepared, a buffer layer 222, an active layer 223, a gate insulating layer 224, a gate electrode 225, an interlayer insulating layer 226, a source electrode 227a, a drain electrode 227b, a passivation layer 221, a pixel-defining layer 229, and a pixel electrode 228a are stacked on the first substrate 210 in this order. Since the above stacking method is performed in the same or similar manner to a method of manufacturing a general display device, a detailed description thereof is omitted.

After stacking the respective layers on the first substrate 210, an EML may be formed on the pixel electrode 228a in a pixel defined by the pixel-defining layer 229 by using a fine metal mask method and an LITI method. The EML may be formed together with or separately from other layers described above. For convenience of explanation, it is assumed herein that the EML is formed separately from other layers.

When the EML is formed as described above, first, a blue EML is deposited on the pixel electrode 228a by using the fine metal mask, followed by formation of green and red EMLs.

In this case, at least one of the green and red EMLs may be deposited on the pixel electrode 228a by using an LITI method. For convenience of explanation, it is assumed hereinafter that the green and red EMLs are sequentially transferred by using the LITI method.

Furthermore, the EML may further include various other color EMLs. The EML may include a white EML, and in this case, the white EML may include blue, green, and red EMLs. Since the white EML is formed in the same manner as described above, a detailed description thereof is omitted.

In order to form the green EML, first, an upper film 240 is prepared. The upper film 240 may be formed by preparing a base film 241 and transferring a transfer layer 243 having the green EML patterned thereon onto the base film 241. The upper film 240 may further include a light-to-heat conversion layer 242 disposed between the base film 241 and the transfer layer 243. For convenience of explanation, the upper film 240 is assumed hereinafter to include the base film 241, the light-to-heat conversion layer 242, and the transfer layer 243.

Light emitted by a light source is absorbed in the light-to-heat conversion layer 242 on the base film 241 and converted into thermal energy. The thermal energy may then cause a change in an adhesion force between the first substrate 210 and the light-to-heat conversion layer 242 and the transfer layer 243 so that a material of the transfer layer 243 overlying the light-to-heat conversion layer 242 is transferred to the first substrate 210. Thus, an EML is patterned on the first substrate 210.

Simultaneously with preparing the upper film 240 as described above, a lower film 250 on which the first substrate 210 is seated is prepared. The upper film 240 may be disposed on the first substrate 210.

After completing the above-described arrangement, the upper and lower films 240 and 250 may be laminated with each other through venting. In such embodiments, since the upper and lower films 240 and 250 have larger planar dimensions than the first substrate 210, they may be bonded to each other where they extend beyond the edges of the first substrate 210.

When the upper film 240 is attached to the lower film 250 as described above, the upper film 240 is bent to follow the chamfered shapes of the edges of the first substrate 210 while the lower film 250 is straight like a lower surface of the first substrate 210.

In particular, when upper and lower films are attached to each other according to conventional methods whereby an edge of a first substrate is not chamfered, the upper and lower films may not completely adhere to each other at edges of the first substrate.

Conversely, according to embodiments of the disclosed technology, the upper and lower films 240 and 250 can be completely attached to each other at the edges of the first substrate 210 to thereby substantially preventing their separation due to external shocks.

After completing adhesion between the upper and lower films 240 and 250 as described above, a laser beam is irradiated from above the upper film 240 to thereby transfer the green EML onto the pixel electrode 228a.

Following the above thermal transfer, the upper and lower films 240 and 250 are separated from the first substrate 210. Since a process of removing the upper and lower films 240 and 250 is performed in a similar manner to a general LITI process, a detailed description thereof is omitted.

After transferring the green EML as described above, the red EML may be transferred by using a similar process to that for transferring the green EML.

Upon completion of the stacking of the green and red EMLs as described above, an opposite electrode (not shown) may be disposed on the pixel-defining layer 229. Since the opposite electrode is formed in the same manner as generally known methods, a detailed description thereof will be omitted.

After forming the opposite electrode, the first substrate 210 is sealed to the sealing portion in the same manner as described above.

In another embodiment, the display device may be manufactured by performing the above-described process on a mother substrate including a plurality of the first substrates 210 and separating the plurality of the first substrates 210 from one another. Since a method of separating the first substrates 210 is the same as a general separation method, a detailed description thereof will be omitted.

As described above, the method of manufacturing the display device according to the present embodiment allows complete attachment between the upper and lower films 240 and 250 at the edges of the first substrate 210, thereby improving the adhesive force therebetween.

The method also eliminates a portion where the upper film 240 is not attached to the lower film 250 due to the thickness of the first substrate 210 to thereby prevent movement of the first substrate 210 and allow transfer of the EML onto a precise location on the pixel-defining layer 229.

Of particular note, the display device thus manufactured includes the precise transfer of the EML, thereby providing increased brightness and reproducibility.

FIG. 5 is a cross-sectional view illustrating a process of forming the EML shown in FIG. 2, according to another embodiment of the disclosed technology. Hereinafter, like numbers refer to like elements.

Referring to FIG. 5, a display device (not indicated in FIG. 5) includes a first substrate 310, a sealing portion (not shown), and a light-emitting portion (not shown). Since the sealing portion and the light-emitting portion have the same or similar functions and structures as described above, detailed descriptions thereof will be omitted.

At least one edge of the first substrate 310 may be chamfered. More specifically, the first substrate 310 may have a sloped edge formed through a polishing process. In particular, the edge of the first substrate 310 may be sloped from the other surface of the first substrate 310 on which the light-emitting portion is not formed towards an edge thereof.

A method of manufacturing the display device having the above-described structure will now be described in detail with reference to FIG. 5.

Referring to FIG. 5, first, the first substrate 310 is prepared with its edges chamfered by mechanical polishing. In this case, the edges of the first substrate 310 may have a triangular cross-section in a thickness direction of the first substrate 310. In particular, the edges of the other surface of the first substrate 310 may be chamfered. Thus, the edges of the first substrate 210 may be sloped from the other surface of the first substrate 310 towards edges thereof.

When the first substrate 310 is large in size, a single substrate is used as the first substrate 310. Conversely, when the first substrate 310 is small in size, a mother substrate (not shown) including a plurality of the first substrates 310 may be used. Since the display device is manufactured in a similar manner regardless of the size of the first substrate 310, for convenience of explanation, it is assumed hereinafter that the first substrate 310 is a single substrate.

The first substrate 310 may have various shapes including a circle, a rectangle, and a polygon. For convenience of explanation, the first substrate 310 is assumed to have a rectangular shape.

The first substrate 310 having a rectangular shape may have at least one edge chamfered in a similar manner as described above. For convenience of explanation, however, it is assumed herein that all four edges of the first substrate 310 are chamfered.

Once the first substrate 310 with the chamfered edges is prepared, a buffer layer 322, an active layer 323, a gate insulating layer 324, a gate electrode 325, an interlayer insulating layer 326, a source electrode 327a, a drain electrode 327b, a passivation layer 321, a pixel-defining layer 329, and a pixel electrode 328a are stacked on the first substrate 310 in this order. Since the above stacking method is performed in the same or similar manner to generally known methods of manufacturing a display device, a detailed description thereof will be omitted.

After stacking the respective layers on the first substrate 310, an EML may be formed on the pixel electrode 328a in a pixel defined by the pixel-defining layer 329 by using a fine metal mask method and an LITI method. The EML may be formed together with or separately from other layers described above. For convenience of explanation, it is assumed herein that the EML is formed separately from other layers.

When the EML is formed as described above, first, a blue EML is deposited on the pixel electrode 328a by using the fine metal mask, followed by formation of green and red EMLs. In this case, at least one of the green and red EMLs may be deposited on the pixel electrode 328a by using an LITI method. For convenience of explanation, it is assumed hereinafter that the green and red EMLs are sequentially transferred by using the LITI method.

More specifically, in order to form the green EML, first, an upper film 340 is prepared. The upper film 340 may be formed by preparing a base film 341 and transferring a transfer layer 343 having the green EML patterned thereon onto the base film 341. The upper film 340 may further include a light-to-heat conversion layer 342 disposed between the base film 341 and the transfer layer 343. For convenience of explanation, the upper film 340 is assumed hereinafter to include the base film 341, the light-to-heat conversion layer 342, and the transfer layer 343.

Light emitted by a light source is absorbed by the light-to-heat conversion layer 342 on the base film 341 and converted into thermal energy. The thermal energy may then cause a change in an adhesion force between the first substrate 310 and the light-to-heat conversion layer 342 and the transfer layer 343 so that a material of the transfer layer 343 overlying the light-to-heat conversion layer 342 is transferred to the first substrate 310. Thereby, an EML is patterned on the first substrate 310.

Simultaneously with preparing the upper film 340 as described above, a lower film 350 on which the first substrate 310 is seated is prepared. The upper film 340 may be disposed on the first substrate 310.

After completing the above-described arrangement, the upper and lower films 340 and 350 may be laminated with each other through venting. In such embodiments, since the upper and lower films 340 and 350 are larger than the first substrate 310, they may be bonded to each other at edges of the first substrate 310.

When the upper film 340 is attached to the lower film 350 as described above, the upper film 340 is bent to follow the chamfered shapes of the edges of the first substrate 310 while the lower film 350 is straight like an upper surface of the first substrate 310.

In particular, when upper and lower films are attached to each other according to conventional methods whereby an edge of a first substrate is not chamfered, the upper and lower films may not completely adhere to each other at edges of the first substrate.

Conversely, according to embodiments of the disclosed technology, the upper and lower films 340 and 350 can be completely attached to each other at the edges of the first substrate 310 to thereby substantially prevent their separation due to external shocks.

After completing adhesion between the upper and lower films 340 and 350 as described above, a laser beam is irradiated from above the upper film 340 to thereby transfer the green EML onto the pixel electrode 328a.

Following the above thermal transfer, the upper and lower films 340 and 350 are separated from the first substrate 310. Since a process of removing the upper and lower films 340 and 350 is performed in a similar manner to a general LITI process, a detailed description thereof is omitted.

After transferring the green EML as described above, the red EML may be transferred by using a similar process to that for transferring the green EML.

Upon completion of the stacking of the green and red EMLs as described above, an opposite electrode (not shown) may be disposed on the pixel-defining layer 329. Since the opposite electrode is formed in the same manner as a general method, a detailed description thereof will be omitted.

After forming the opposite electrode, the first substrate 310 is sealed to the sealing portion in the same manner as described above.

In another embodiment, the display device may be manufactured by performing the above-described process on a mother substrate including a plurality of the first substrates 310 and separating the plurality of the first substrates 310 from one another. Since a method of separating the first substrates 310 is the same as generally known separation methods, a detailed description thereof will be omitted.

As described above, the method of manufacturing the display device according to the present embodiment allows complete attachment between the upper and lower films 340 and 350 at the edges of the first substrate 310, thereby improving the adhesive force therebetween.

The method also eliminates a portion where the upper film 340 is not attached to the lower film 350 due to the thickness of the first substrate 310 to thereby prevent movement of the first substrate 310 and allow transfer of the EML onto a precise location on the pixel-defining layer 329.

In particular, the display device thus manufactured includes the precise EML transfer, thereby providing increased brightness and reproducibility.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A display device, comprising:
a first substrate;
a light-emitting portion formed on the first substrate; and
a sealing portion which is attached to the first substrate so as to protect the light-emitting portion from ambient environmental conditions,
wherein at least a portion of an edge of the first substrate is chamfered.

2. The device of claim 1, wherein the edge of the first substrate has a triangular cross-section in a thickness dimension.

3. The device of claim 1, wherein the edge of the first substrate is chamfered from one surface of the first substrate on which the light-emitting portion is formed towards an edge thereof.

4. The device of claim 1, wherein the edge of the first substrate is chamfered from the other surface of the first substrate on which the light-emitting portion is not formed towards an edge thereof.

5. The device of claim 1, wherein distal ends of the first substrate are respectively chamfered from both surfaces of the first substrate towards edges of the first substrate.

6. The device of claim 1,
wherein the light-emitting portion includes an organic emission layer, and
wherein the organic emission layer includes at least one of a blue emission layer, a red emission layer, a green emission layer, and a white emission layer.

7. The device of claim 6, wherein the blue emission layer is formed by using a fine metal mask process.

8. The device of claim 6, wherein at least one of the red and green emission layers is formed by using a laser-induced thermal imaging (LITI) process.

9. The device of claim 6, wherein the white emission layer is formed from a stack of the blue, red and green emission layers.

10. A method of manufacturing a display device, the method comprising:
providing a first substrate with chamfered edges;
stacking a buffer layer, an active layer, a gate insulating layer, a gate electrode, an interlayer insulating layer, a source electrode, a drain electrode, a passivation layer, a pixel-defining layer, and a pixel electrode on the first substrate in this order; and
forming, by a fine metal mask process and a laser-induced thermal imaging (LITI) process, an organic emission layer on the pixel electrode in a pixel defined by the pixel-defining layer.

11. The method of claim 10, wherein the edges of the first substrate are chamfered by using a polishing process.

12. The method of claim 10, wherein the forming of the organic emission layer includes depositing a blue emission layer on the pixel electrode by using the fine metal mask process and transferring green and red emission layers onto the pixel electrode by using the LITI process.

13. The method of claim 12, wherein the LITI process includes transferring the green emission layer onto the pixel electrode and then depositing the red emission layer on the pixel electrode.

14. The method of claim 12, wherein the transferring of the green and red emission layers onto the pixel electrode by the LITI process includes:
seating the first substrate on a lower film;
preparing an upper film by depositing a transfer layer having one of the red and green emission layers patterned thereon on a base film;
disposing the upper film on the first substrate and laminating the upper and lower films by venting; and
irradiating the upper film with a laser beam and transferring the one of the red and green emission layers onto the pixel electrode.

15. The method of claim 14, wherein the transferring of the green and red emission layers onto the pixel electrode further includes removing the upper and lower films after irradiation with the laser beam.

16. The method of claim 10, further comprising forming an opposite electrode on the pixel-defining layer on which the organic emission layer has been formed and sealing the opposite electrode with a sealing portion.

17. The method of claim 10, further comprising cutting the first substrate into a plurality of substrates and separating the plurality of substrates from one another.

18. The method of claim 10, wherein the forming of the organic emission layer includes forming a white emission layer by depositing or transferring blue, green, and red emission layers.
